(19) United States
(12) Patent Application Publication
(10) Pub. No.: US 2019/0319099 A1
(43) Pub. Date: Oct. 17, 2019

(54) VERTICAL TRANSISTORS HAVING IMPROVED CONTROL OF PARASITIC CAPACITANCE AND SOURCE/DRAIN-TO-CHANNEL RESISTANCE

(71) Applicant: International Business Machines Corporation, Armonk, NY (US)

(72) Inventors: Kangguo Cheng, Schenectady, NY (US); Xin Miao, Guilderland, NY (US); Wenyu Xu, Albany, NY (US); Chen Zhang, Guilderland, NY (US)

(21) Appl. No.: 15/950,618

(22) Filed: Apr. 11, 2018

(51) Int. Cl. H01L 29/08; H01L 29/78; H01L 29/10; H01L 29/66

(52) U.S. Cl. CPC H01L 29/0847; H01L 29/7827; H01L 29/6656; H01L 29/66666; H01L 29/1037

(57) ABSTRACT

Embodiments of the invention are directed to semiconductor device that includes a channel fin formed across from a substrate. A gate is formed across from the substrate and along a sidewall surface of the channel fin, wherein the gate includes a gate top surface. A source or drain (S/D) region having a S/D region bottom surface is formed such that a first portion of the S/D region extends over the channel fin, and such that a second portion of the S/D region extends over the gate. A first portion of the S/D region bottom surface is configured to have a first predetermined distance from a first portion of the gate top surface. A second portion of the S/D region bottom surface is configured to have a second predetermined distance from a second portion of the gate top surface. The first predetermined distance is less than the second predetermined distance.

### BACKGROUND

The present invention relates in general to semiconductor devices and their fabrication. More specifically, the present invention relates to improved fabrication methodologies and resulting structures for vertical field effect transistors (VFETs) configured and arranged to provide improved control over drain-to-gate (or source-to-gate) parasitic capacitance and/or source/drain-to-channel resistance.

Semiconductor devices are typically formed using active regions of a wafer. In an integrated circuit (IC) having a plurality of metal oxide semiconductor field effect transistors (MOSFETs), each MOSFET has a source and a drain that are formed in an active region of a semiconductor layer by incorporating n-type or p-type impurities in the layer of semiconductor material. A conventional geometry for MOSTFETs is known as a planar device geometry in which the various parts of the MOSFET device are laid down as planes or layers.

A type of MOSFET is a non-planar FET known generally as a VFET. VFETs employ semiconductor fins and side-gates that can be contacted outside the active region, resulting in increased device density and some increased performance over lateral devices. In VFETs the source to drain current flows in a direction that is perpendicular to a major surface of the substrate. For example, in a known VFET configuration a major substrate surface is horizontal and a vertical fin extends upward from the substrate surface. The fin forms the channel region of the transistor. A source region and a drain region are situated in electrical contact with the top and bottom ends of the channel region, while a gate is disposed on one or more of the fin sidewalls. An important parameter in VFET designs is controlling drain-to-gate parasitic capacitance.

### SUMMARY

Embodiments of the invention are directed to a method of forming a semiconductor device. A non-limiting example of the method includes forming a channel fin structure across from a major surface of a substrate. A gate structure is formed across from the major surface of the substrate and along a sidewall surface of the channel fin structure, wherein the gate structure includes a gate structure top surface. A source or drain (S/D) region having a S/D region bottom surface is formed such that a first portion of the S/D region extends over the channel fin structure, and such that a second portion of the S/D region extends over the gate structure. A first portion of the S/D region bottom surface is configured to have a first predetermined distance from a first portion of the gate structure top surface. A second portion of the S/D region bottom surface is configured to have a second predetermined distance from a second portion of the gate structure top surface. The first predetermined distance is less than the second predetermined distance.

Embodiments of the invention are directed to semiconductor device. A non-limiting embodiments of the semiconductor device includes a channel fin structure formed across from a major surface of a substrate. A gate structure is formed across from the major surface of the substrate and along a sidewall surface of the channel fin structure, wherein the gate structure includes a gate structure top surface. A S/D region having a S/D region bottom surface is formed such that a first portion of the S/D region extends over the channel fin structure, and such that a second portion of the S/D region extends over the gate structure. A first portion of the S/D region bottom surface is configured to have a first predetermined distance from a first portion of the gate structure top surface. A second portion of the S/D region bottom surface is configured to have a second predetermined distance from a second portion of the gate structure top surface. The first predetermined distance is less than the second predetermined distance.

Additional features and advantages are realized through the techniques described herein. Other embodiments and aspects are described in detail herein. For a better understanding, refer to the description and to the drawings.

### BRIEF DESCRIPTION OF THE DRAWINGS

The subject matter which is regarded as the present invention is particularly pointed out and distinctly claimed in the claims at the conclusion of the specification. The foregoing and other features and advantages are apparent from the following detailed description taken in conjunction with the accompanying drawings in which:

FIG. 1 depicts a two-dimensional (2D) cross-sectional view of a known VFET device having unwanted drain-to-gate parasitic capacitance;

FIG. 2A depicts a 2D cross-sectional view of a VFET semiconductor device that includes a top spacer having a top surface topology configured and arranged to create varying separation distances between the VFET gate and the VFET source/drain (S/D), wherein the varying separation distances are selected to, in accordance with embodiments of the invention, reduce parasitic capacitance and concurrently minimize any increase in the current resistance between the S/D and the VFET channel;

FIG. 2B depicts a 2D cross-sectional and partially exploded view of the VFET semiconductor device shown in FIG. 2A, wherein the top S/D region has been separated from the remainder of the VFET semiconductor device to better illustrate the bottom surfaces of the top S/D region and the top surfaces of the top spacers;

FIGS. 3-8 depict 2D cross-sectional views of a VFET semiconductor device after fabrication operations in accordance with aspects of the invention, wherein:

FIG. 3 depicts a 2D cross-sectional view of a VFET semiconductor device according to embodiments of the invention;

FIG. 4 depicts a 2D cross-sectional view of a semiconductor structure after a fabrication operation according to embodiments of the invention;

FIG. 5 depicts a 2D cross-sectional view of a semiconductor device after a fabrication operation according to embodiments of the invention;

FIG. 6 depicts a 2D cross-sectional view of a semiconductor device after a fabrication operation according to embodiments of the invention;

FIG. 7 depicts a 2D cross-sectional view of a semiconductor device after a fabrication operation according to embodiments of the invention; and

FIG. 8 depicts a 2D cross-sectional view of a semiconductor device after a fabrication operation according to embodiments of the invention.

In the accompanying figures and following detailed description of the embodiments, the various elements illustrated in the figures are provided with three or four digit reference numbers. The leftmost digit(s) of each reference number corresponds to the figure in which its element is first illustrated.

### DETAILED DESCRIPTION

It is understood in advance that, although this description includes a detailed description of the formation and resulting structures for a specific type of VFET, implementation of the teachings recited herein are not limited to a particular type of VFET or IC architecture. Rather embodiments of the present invention are capable of being implemented in conjunction with any other type of VFET or IC architecture, now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

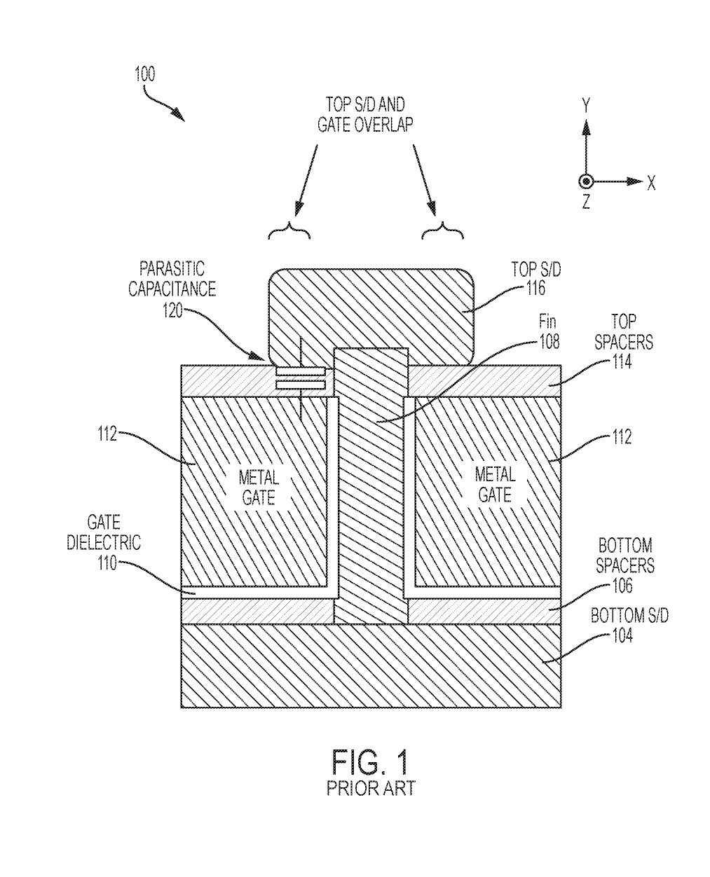

Turning now to an overview of technologies that are more specifically relevant to aspects of the present invention, as previously noted herein, some non-planar transistor device architectures, such as VFETs, employ semiconductor fins and side-gates that can be contacted outside the active region, resulting in increased device density over lateral devices. FIG. 1 depicts a two-dimensional (2D) cross-sectional view of a known VFET device 100 having unwanted drain-to-gate parasitic capacitance 120. The VFET device 100 includes a bottom source/drain (S/D) region 104 (formed over a substrate (not shown)), bottom spacers 106, a channel fin 108, a gate dielectric 110, a gate structure 112, top spacers 114, and a top S/D region 116, configured and arranged as shown. With reference to the X/Y/Z diagram depicted in FIG. 1, the various elements that form the VFET device 100 extend along a first axis (e.g., X-axis) to define width dimensions, and extend along a second axis (e.g., Y-axis) perpendicular to the X-axis to define height (or thickness) dimensions. Although not specifically depicted in the 2D cross-sectional view shown in FIG. 1, the various elements that form the VFET device 100 also extend along a third axis (e.g., Z-axis) perpendicular to the first axis and the second axis to define depth dimensions. In accordance with standard VFET architectures, various elements of the VFET 100 (e.g., bottom spacers 106, gate dielectric 110, gate structure 112, top spacer 114 and top S/D region 116) extend completely around the sidewalls of the channel fin 108 in the X, Y, and Z directions.

A problem with known VFET designs of the type shown in FIG. 1 is controlling unwanted parasitic capacitance 120 between the top S/D region 116 and the gate structure 112. The parasitic capacitance 120 is primarily due to the overlap between the top S/D region 116 and the gate structure 112. Parasitic capacitance 120 degrades VFET performance in a number of ways, including, for example, reducing circuit speed and increasing power consumption. Known attempts to reduce parasitic capacitance 120 require a tradeoff between reducing unwanted parasitic capacitance and increasing resistance between the top S/D region 116 and the channel fin 108. For example, the resistance between the top S/D region 116 and the channel fine 108 can be reduced by increasing the size or volume of the top S/D region 116. However, increasing the size/volume of the top S/D region 116 will increase the amount of the top S/D region 116 that overlaps the gate structure 112, which will increase parasitic capacitance 120. Similarly, the parasitic capacitance 120 can be reduced by increasing the thickness dimension of the top spacers 114, which results in an increased distance between the top S/D region 116 and the metal gate 112. However, increasing the distance between the top S/D region 116 and the gate structure 112 will decrease the amount of surface area of the top S/D region 116 that contacts the channel fin 108, which increases the resistance between the top S/D region 116 and the channel fine 108.

Turning now to an overview of aspects of the present invention, embodiments of the invention provide improved fabrication methodologies and resulting structures for VFETs having improved drain-to-gate (or source-to-gate) parasitic capacitance control. Embodiments of the invention leverage the observation that the resistance between the top S/D region and the channel fin is primarily influenced by the volume/size of the top S/D region and the amount of surface area of the top S/D region that contacts the channel fin. Embodiments of the invention further leverage the observation that the parasitic capacitance (e.g., parasitic capacitance 120 shown in FIG. 1) between the top S/D region and the gate structure is primarily influenced by the distance between the top S/D region and the gate structure, as well as by the amount of the top S/D region that overlaps the gate structure. Embodiments of the invention leverage the above-described observations (individually or in various combinations) by providing a VFET semiconductor device that includes a top spacer positioned between the top S/D region and the gate structure. In accordance with aspects of the invention, the top spacer is a multi-dimensional structure that includes a top spacer surface topology configured and arranged to create/define varying separation distances between the VFET gate and the VFET top S/D region. In embodiments of the invention, the varying separation distances can be selected (i.e., mixed and matched) to reduce parasitic capacitance and concurrently minimize any increase in the current resistance between the top S/D region and the channel fin. In embodiments of the invention, the varying separation distances can be selected to concurrently tune unwanted parasitic capacitance and the resistance between the top S/D region and the channel fin such that they both fall within a range of acceptable parameters for the particular VFET application. In some embodiments of the invention, the unwanted parasitic capacitance can be tuned such that is it substantially eliminated.

In embodiments of the invention, the top spacer surface topology can be further configured and arranged to include varying width dimensions that define corresponding varying width dimensions of the bottom surface of the top S/D region. In embodiments of the invention, the varying width dimensions can be selected to reduce parasitic capacitance and concurrently minimize any increase in the current resistance between the top S/D region and the channel fin. In embodiments of the invention, the varying width dimensions can be selected to concurrently tune unwanted parasitic capacitance and the resistance between the top S/D region and the channel fin such that they both fall within a range of acceptable parameters for the particular VFET application. In some embodiments of the invention, in addition to the varying separation distances and width dimensions, the volume/size of the top S/D region can also be selected to concurrently tune unwanted parasitic capacitance and the resistance between the top S/D region and the channel fin such that they both fall within a range of acceptable parameters for the particular VFET application.

In embodiments of the invention, a VFET semiconductor device that achieves the concurrent tuning of parasitic capacitance and S/D/channel resistance can be fabricated by forming a channel fin structure across from a major surface of a substrate. A gate structure is formed across from the major surface of the substrate and along sidewall surfaces of the channel fin structure, wherein the gate structure includes a gate structure top surface. A S/D region having a S/D region bottom surface is formed such that a first portion of the S/D region extends over the channel fin structure. The S/D region is further formed such that a second portion of the S/D region extends over the gate structure. A first portion of the S/D region bottom surface is configured to have a first predetermined distance from a first portion of the gate structure top surface, and a second portion of the S/D region bottom surface is configured to have a second predetermined distance from a second portion of the gate structure top surface.

In embodiments of the invention, the parasitic capacitance can be tuned by, inter alia, selecting the first predetermined distance to be less than the second predetermined distance. In embodiments of the invention, the S/D/channel resistance can be tuned by configuring a size of the S/D region to define a predetermined S/D region volume and selecting the predetermined S/D volume and the first predetermined distance to provide a predetermined current resistance between the S/D region and the channel fin structure. In embodiments of the invention, the first predetermined distance tunes the S/D/channel resistance by increasing or decreasing the amount of the top S/D region surface area that contacts the channel fin structure. A thinner first predetermined distance increases the amount of the top S/D region surface area that contacts the channel fin structure, thereby decreasing the S/D/channel resistance. Similarly, a thicker first predetermined distance decreases the amount of the top S/D region surface area that contacts the channel fin structure, thereby increasing the S/D/channel resistance.

In embodiments of the invention, the above-described VFET fabrication operations can further include configuring a third portion of the S/D region bottom surface to have a third predetermined distance from a third portion of the gate structure top surface. In embodiments of the invention, the parasitic capacitance can be tuned by, inter alia, selecting the second predetermined distance to be less than the third predetermined distance. In embodiments of the invention, the S/D/channel resistance can be further tuned by further configuring the top spacer to separate the third portion of the S/D region bottom surface from the third portion of the gate structure top surface by the third predetermined distance.

In embodiments of the invention, the above-described VFET fabrication operations can further include forming a top spacer positioned between the top S/D region and the gate structure. The top spacer includes a top spacer surface topology configured and arranged to create/define the above-described first, second, or third predetermined separation distances. In embodiments of the invention, the top spacer topology is further configured and arranged to create/define the above described varying width dimensions.

As previously noted herein, the above-described separation distances, width dimensions, and top S/D size/volume can be configured and arranged to achieve the necessary parasitic capacitance and S/D/channel resistance for the specific application. For example, the first predetermined separation distance can be selected to have a value X, which positions a first portion of the bottom surface of the top S/D region sufficiently far away from the gate structure to result in a parasitic capacitance that is within an acceptable range for the specific application. However, in this example, setting the first predetermined separation distance at X has the undesired result of reducing the surface area of the top S/D region that contacts the channel fin, which has the further undesired result of increasing the S/D/channel resistance. According to embodiments of the invention, the undesired increase in the S/D/channel resistance can be offset by increasing the size/volume of the SD region, which can be accomplished by extending a duration of an epitaxial growth process used to form the top S/D region. Without benefit of aspects of the invention, and as previously noted herein, the parasitic capacitance (e.g., parasitic capacitance 120 shown in FIG. 1) between the top S/D region and the gate structure would ordinarily be increased by increasing the size/volume of the top S/D region, which increases the amount of the top S/D region that overlaps the gate structure. However, because, according to embodiments of the invention, portions of the top S/D region are at the second predetermined separation distance and/or the third predetermines separation distance, the second predetermined separation distance and/or the third predetermines separation distance can be set at a sufficiently large value to provide a reduction in parasitic capacitance that counters and/or offsets any increase in parasitic capacitance that results from increasing the size/volume of the top S/D region, which increases the amount of the top S/D region that overlaps the gate structure.

In embodiments of the invention, the top spacer surface topology can be implemented by providing a multi-segmented top spacer configured and arranged to provide a “stair-stepped” or “staircase” top surface topology, which results in a corresponding (or mirror-image matching) stair-stepped or staircase bottom surface topology in the top S/D region. For example, the multi-segmented top spacer surface can be formed from a first spacer region, a second spacer region and a third spacer region, which can be stacked one on top of the other. When the first, second and third spacer regions are stacked, the first spacer region has a first thickness dimension and a first width dimension; the second spacer region has a second thickness dimension and a second width dimension; and the third spacer region has a third thickness dimension and a third width dimension. The first, second and third width dimensions are selected such that the first width dimension is greater than the second width dimension, and the second width dimension is greater than the third width dimension. Accordingly, when the second spacer region is stacked on the first spacer region, and when the third spacer region is stacked on the second spacer region, the combined exposed top surfaces of the first, second, and third spacer regions form a stair-stepped configuration.

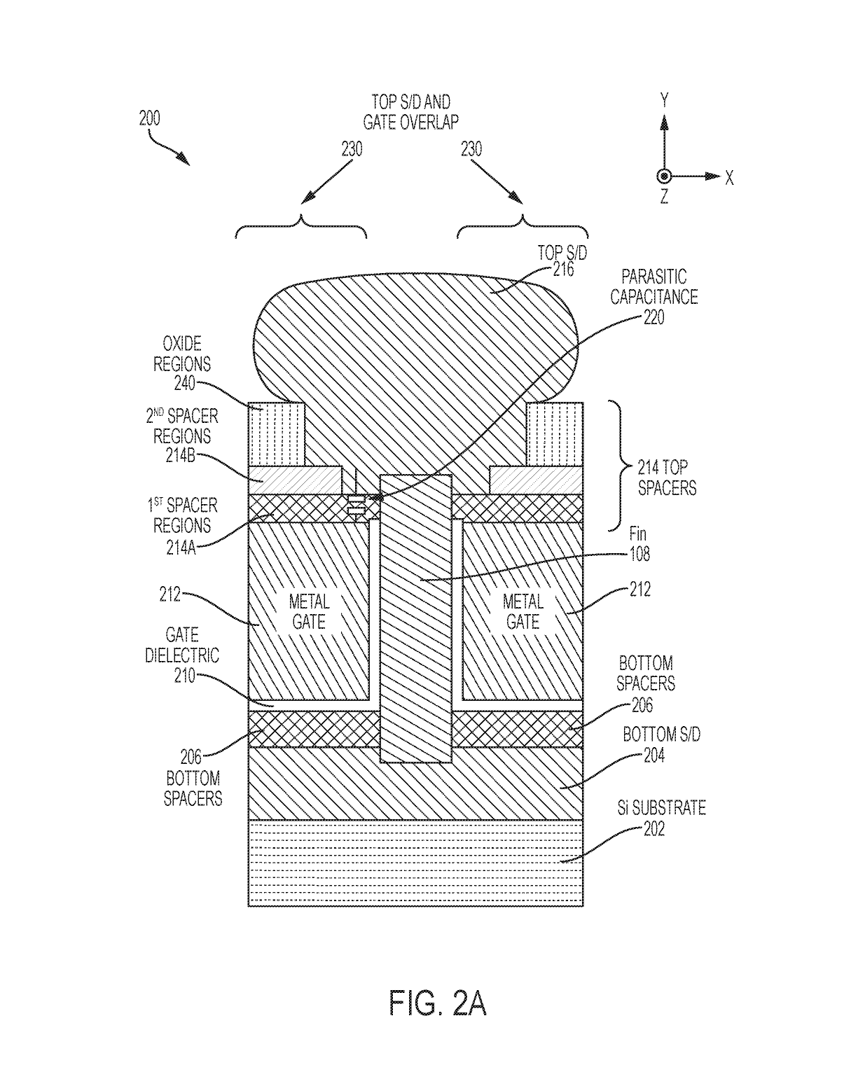

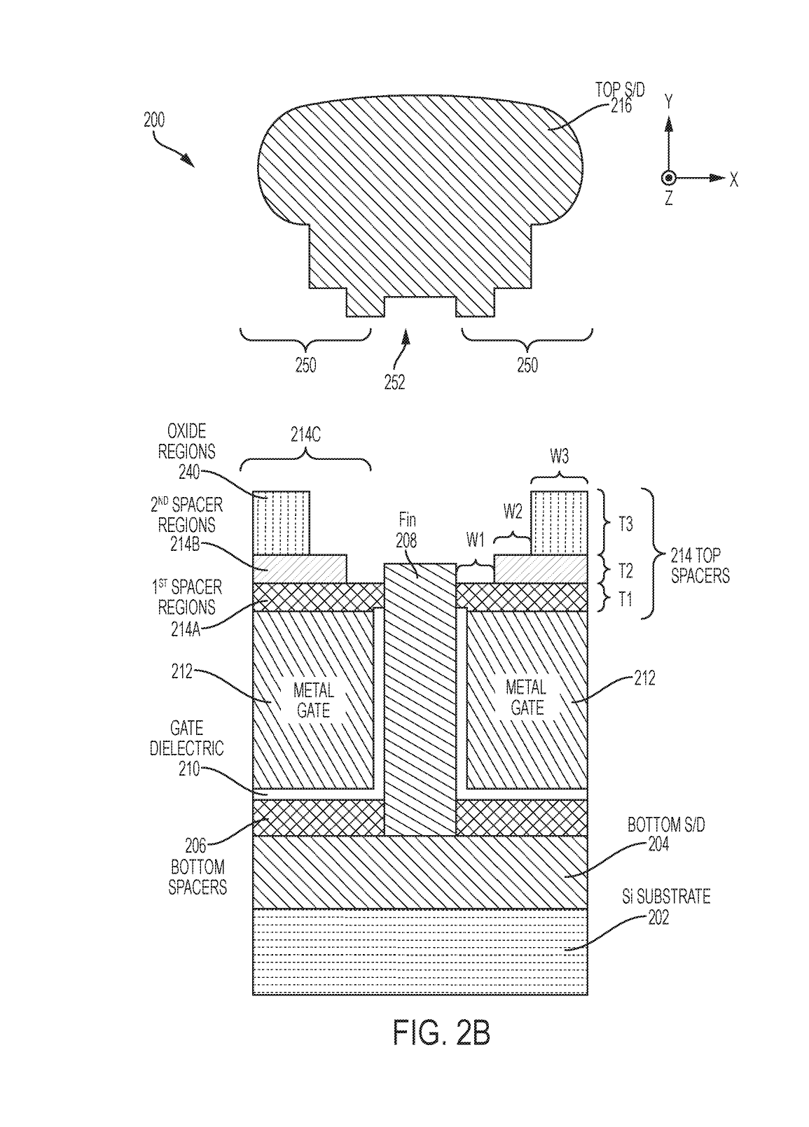

Turning now to a more detailed description of aspects of the invention, FIG. 2A depicts a 2D cross-sectional view of a VFET semiconductor device 200 that includes top spacers 214 having top surface topologies 214C (shown in FIG. 2B) configured and arranged to create varying separation distances T1, T2, T3 (shown in FIG. 2B) between gate structures 212 and bottom surfaces 250 (shown in FIG. 2B) of a top S/D region 216, wherein the varying separation distances T1, T2, T3 can be selected to, in accordance with embodiments of the invention, reduce parasitic capacitance 220 and concurrently minimize any increase in the resistance between the top S/D region 216 and a channel fin 208 of the VFET device 200. FIG. 2B depicts a 2D cross-sectional and partially exploded view of the VFET semiconductor device 200, which is identical to the VFET semiconductor device 200 shown in FIG. 2A except the top S/D region 216 is shown, for illustration purposes, as separated from the remainder of the VFET semiconductor device 200 to better illustrate the bottom surfaces 250, 252 of the top S/D region 216, the top surfaces 214C of the top spacers 214, the width dimensions W1, W2, W3, and the thickness/height dimensions T1, T2, T3.

With reference to the X/Y/Z diagram depicted in FIGS. 2A and 2B, the various elements that form the VFET device 200 extend along a first axis (e.g., X-axis) to define width dimensions, and a second axis (e.g., Y-axis) perpendicular to the X-axis to define height (or thickness) dimensions. Although not specifically depicted in the 2D cross-sectional views shown in FIGS. 2A and 2B, the various elements that form the VFET device 200 also extend along a third axis (e.g., Z-axis) perpendicular to the first axis and the second axis to define depth dimensions. Although not depicted in the 2D diagrams shown in FIGS. 2A and 2B, the various elements that form the VFET 200 (e.g., bottom spacers 206, gate dielectric 210, gate structure 212, top spacer 214 and top S/D region 216) extend completely around the sidewalls of the channel fin 208 in the X, Y, and Z directions.

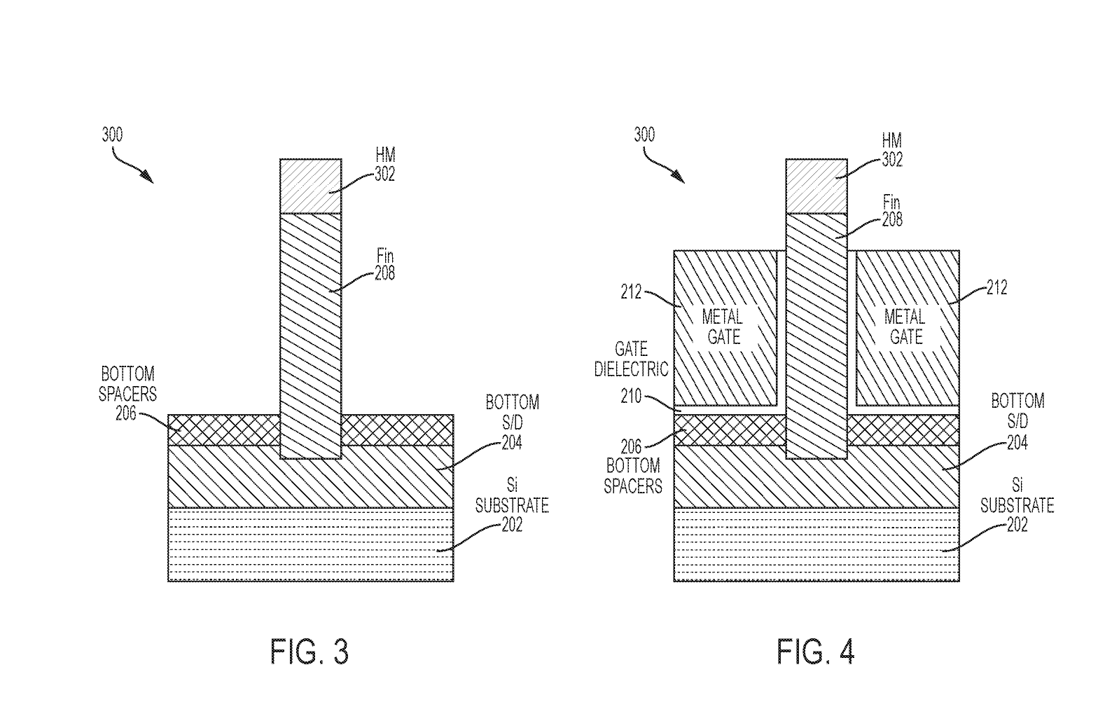

VFET 200 includes a substrate 202, a doped bottom S/D region 204, bottom spacers 206, a channel fin 208, a gate dielectric 210, a gate structure 212, top spacers 214, and a top S/D region 216, configured and arranged as shown. VFET 200 can be fabricated according to the fabrication methodologies illustrated in FIGS. 3-8 and describe in detail subsequently herein. Subsequent fabrication processes (e.g., gate contacts, etc.) are applied to VFET 200 to form a finished semiconductor device. The details of suitable subsequent fabrication processes to form a finished VFET semiconductor device are known to those skilled in the art so have been omitted in the interest of brevity.

The top spacers 214 provide electrical isolation between the gate structure 212 and the top S/D region 216. The top spacers 214 also define the distance between the gate structure 212 and the top S/D region 216, which impacts the presence and the extent of unwanted capacitance 220 between the gate structure 212 and the top S/D region 216. As shown in FIGS. 2A and 2B, the top spacers 214 include a novel multi-dimensional configuration, which includes thickness dimensions T1, T2, T3 and width dimensions W1, W2, W3. Although 3 thickness dimensions and 3 width dimensions are used in the embodiments of the invention illustrated and described herein, it is understood that other embodiments of the invention can provide multi-dimensional top spacers having any number of utilize any number thickness and width dimensions.

In embodiments of the invention, the multi-dimensional top spacer 214 includes a first spacer region 214A that defines T1, a second spacer region 214B that defines T2, and an oxide region 240 that defines T3. When stacked one on top of the other in the manner shown in FIGS. 2A and 2B, a top surface of the first spacer region 214A defines W1, a top surface of the second spacer region 214B defines W2, and a top surface of the oxide region 240 defines W3. The combined top surfaces of the first spacer region 214A, the second spacer region 214B, and the oxide region 240 define a top surface topology 214C of the top spacer 214. A bottom surface 250 of the top S/D region 216 is a mirror image of the top surface topology 214C of the top spacer 214. In some embodiments of the invention, instead of forming the multi-dimensional top spacer 214 from multiple components (214A, 214B, 240), the multi-dimensional top spacer 214 can be formed as a single continuous structure.

According to embodiments of the invention, the thickness dimensions T1, T2, T3 and width dimensions W1, W2, W3 are configured and arranged to control, or in some instances eliminate, the amount of unwanted parasitic capacitance 220 between the top S/D region 116 and the gate structure 112. According to embodiments of the invention, the thickness dimensions T1, T2, T3, width dimensions W1, W2, W3, and volume/size of the top S/D region 216 are configured and arranged to control the amount of resistance between the top S/D region 216 and the channel fin 208. According to embodiments of the invention, the thickness dimensions T1, T2, T3, width dimensions W1, W2, W3, and volume/size of the top S/D region 216 are configured and arranged to control/eliminate the amount of unwanted parasitic capacitance 220 while concurrently controlling the amount of resistance between the top S/D region 216 and the channel fin 208.

The thickness dimensions T1, T2, T3 and the width dimensions W1, W2, W3 of the multi-dimensional top spacers 216 are configured and arranged to leverage the observation that the resistance between the top S/D region 216 and the channel fin 208 is primarily influenced by the volume/size of the top S/D region 216 and the amount of surface area 252 (shown in FIG. 2B) of the top S/D region 216 that contacts the channel fin 208. The thickness dimensions T1, T2, T3 and the width dimensions W1, W2, W3 of the multi-dimensional top spacers 216 are configured and arranged to further leverage the observation that the parasitic capacitance 220 (shown in FIG. 2A) between the top S/D region 216 and the gate structure 212 is primarily influenced by the distance between the top S/D region 216 and the gate structure 212, as well as the amount of the top S/D region 216 that overlaps the gate structure 212 (top S/D and gate overlap 230 shown in FIG. 2A).

In embodiments of the invention, the parasitic capacitance 220 can be tuned by, inter alia, selecting T1 in the W1 region to be less than T1+T2 in the W2 region. In embodiments of the invention, the S/D/channel resistance can be tuned by configuring a size of the top S/D region 216 to define a predetermined volume of the top S/D region 216 and selecting the predetermined S/D volume and T1 in the W1 region to provide a predetermined current resistance between the top S/D region 216 and the channel fin 208. In embodiments of the invention, T1 in the W1 region tunes the S/D/channel resistance by increasing or decreasing the amount of the top S/D region surface area 252 that contacts the channel fin 208. A thinner T1 distance in the W1 region increases the amount of the top S/D region surface area 252 that contacts the channel fin 208, thereby decreasing the S/D/channel resistance. Similarly, a thicker T1 distance in the W1 region decreases the amount of the top S/D region surface area 252 that contacts the channel fin 208, thereby increasing the S/D/channel resistance.

In embodiments of the invention, the parasitic capacitance can be tuned by, inter alia, selecting T1+T2 in the W2 region to be less than T1+T2+T3 in the W3 region. In embodiments of the invention, the S/D/channel resistance can be further tuned by selecting T1+T2+T3 in W3 to separate a portion of the bottom surface 250 of the top S/D region 216 from a portion of the gate structure 212 by the distance T1+T2+T3.

In accordance with embodiments of the invention, the thickness dimensions T1, T2, T3, width dimensions W1, W2, W3, and size/volume of the top S/D region 216 can be configured and arranged to achieve the parasitic capacitance ranges and S/D/channel resistance ranges that are acceptable or required for the specific application. For example, the T1 can be selected to have a value X, which positions a first portion of the bottom surface 250 of the top S/D region 216 sufficiently far away from the gate structure 212 to result in a parasitic capacitance 220 that is within an acceptable range for the specific application. However, in this example, setting T1 at X has the undesired result of reducing the surface area 252 of the top S/D region 216 that contacts the channel fin 208, which has the undesired result of increasing the S/D/channel resistance. According to embodiments of the invention, the undesired increase in the S/D/channel resistance can be offset by increasing the size/volume of the SD region 216, which can be accomplished by extending a duration of an epitaxial growth process used to form the top S/D region 216. Without benefit of aspects of the invention, and as previously noted, the parasitic capacitance 220 between the top S/D region 216 and the gate structure 212 would ordinarily be increased by increasing the size/volume of the top S/D region 216, which increases the amount of the top S/D region 216 that overlaps the gate structure 212 (top S/D and gate overlap 230 shown in FIG. 2A). However, because, according to embodiments of the invention, portions of the top S/D region 216 are separated from the gate structure 212 by T1+T2 and/or T1+T2+T3, the dimensions T1+T2 and/or T1+T2+T3 can be set at a sufficiently large value to provide a reduction in parasitic capacitance 220 that counters and/or offsets any increase in parasitic capacitance 220 that resulted from increasing the size/volume of the top S/D region 216, which increases the amount of the top S/D region 216 that overlaps the gate structure 212 (top S/D and gate overlap 230 shown in FIG. 2A).

FIGS. 3-8 depict 2D cross-sectional views of a semiconductor structure 300 after fabrication operations according to embodiments of the invention. The fabrication operations depicted in FIGS. 3-8 are applied to the semiconductor structure 300 to form the VFET device 200 shown in FIGS. 2A and 2B. As shown in FIG. 3, known semiconductor fabrication operations have been used to form the semiconductor structure 300 having a substrate 202, a bottom S/D region 204 across from a major surface of a substrate 202, a channel fine 208, a hard mask 302, and a bottom spacer 206, configured and arranged as shown. The substrate 202 can be any suitable substrate material, such as, for example, monocrystalline Si, SiGe, SiC, III-V compound semiconductor, II-VI compound semiconductor, or semiconductor-on-insulator (SOI). In some embodiments of the invention, the substrate 202 includes a buried oxide layer (not depicted). In some embodiments of the invention, the bottom S/D region 204 can be formed later in the fabrication process. In some embodiments of the invention, the bottom S/D region 204 is epitaxially grown, and the necessary doping to form the bottom S/D region 204 is provided through in-situ doping during the epitaxial growth process, or through ion implantation after the bottom S/D region 204 is formed. The bottom S/D region 204 can be formed by any suitable doping technique, including but not limited to, ion implantation, gas phase doping, plasma doping, plasma immersion ion implantation, cluster doping, infusion doping, liquid phase doping, solid phase doping, in-situ epitaxy growth, or any suitable combination of those techniques.

Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, germanium, and/or carbon doped silicon (Si:C) can be doped during deposition (in-situ doped) by adding dopants, n-type dopants (e.g., phosphorus or arsenic) or p-type dopants (e.g., boron or gallium), depending on the type of transistor. The dopant concentration in the source/drain can range from 1×10¹⁹ cm ⁻³ to 2×10²¹ cm ³, or preferably between 2×10²⁰ cm⁻³ and 1×10²¹ cm⁻³.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a { 100} orientated crystalline surface will take on a {100} orientation. In some embodiments of the invention, epitaxial growth and/or deposition processes are selective to forming on semiconductor surface, and generally do not deposit material on exposed surfaces, such as silicon dioxide or silicon nitride surfaces.

In some embodiments of the invention, the gas source for the deposition of epitaxial semiconductor material include a silicon containing gas source, a germanium containing gas source, or a combination thereof. For example, an epitaxial Si layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

Continuing with FIG. 3, the channel fin 208 can be formed prior to formation of the bottom spacers 206 by depositing an undoped semiconductor (e.g., Si) region (not shown) 302 across from the doped bottom S/D region 204. The semiconductor region is a precursor to the channel fin 208. In some embodiments of the invention, the undoped semiconductor region is epitaxially grown. If needed, dopants can be intentionally added to the deposited semiconductor region. Typically, if dopants are added to semiconductor region, the added dopant concentration is lower than the dopant concentration in the bottom S/D region 204. A hard mask layer (not shown) is deposited across from the undoped semiconductor region (i.e., the precursor to the channel fin 208) using any suitable deposition process. For example, the hard mask layer can be a dielectric such as silicon nitride (SiN), silicon oxide, or a combination of silicon oxide and silicon nitride. Conventional semiconductor device fabrication processes (e.g., patterning and lithography, self-aligned double patterning, self-aligned quadruple patterning) are used to remove portions of the undoped semiconductor region and the hard mask layer to form the channel fin 208 and the hard mask 302. In some embodiments of the invention, the hard mask layer is patterned to expose portions of the undoped semiconductor region. The exposed portions of the semiconductor region can then be removed or recessed using, for example, a wet etch, a dry etch, or a combination thereof, to thereby form the channel fin 208 and the hard mask 302. The channel fin 208 can be electrically isolated from other regions of the substrate 202 by a shallow trench isolation (not depicted). The shallow trench isolation can be of any suitable dielectric material, such as, for example, a silicon oxide.

Bottom spacers 206 are formed across from the doped S/D region 204 and adjacent to a bottom portion of the channel fin 208. The bottom spacers 206 can include a dielectric material, such as, for example, SiN, SiC, SiOC, SiCN, BN, SiBN, SiBCN, SiOCN, SiOₓN_{y}, and combinations thereof. The dielectric material can be a low-k material having a dielectric constant less than about 7, less than about 5, or even less than about 2.5. The bottom spacers 208 can be formed using known deposition processes, such as, for example, CVD, PECVD, ALD, PVD, chemical solution deposition, or other like processes.

In FIG. 4, a gate dielectric 210 and a gate conductor 212 (e.g., a work function metal (WFM)) have been deposited over the bottom spacer 206 and adjacent to a portion of the channel fin 208. In embodiments of the invention, the gate conductor 212 can be formed by overfilling a gate conductor material above a top surface of the hard mask 302 and planarizing the gate conductor material to a level below the top surface of the channel fine 208 using, for example, CMP.

The gate dielectric 210 can be formed from one or more gate dielectric films. The gate dielectric films can be a dielectric material having a dielectric constant greater than, for example, 3.9, 7.0, or 10.0. Non-limiting examples of suitable materials for the high-k dielectric films include oxides, nitrides, oxynitrides, silicates (e.g., metal silicates), aluminates, titanates, nitrides, or any combination thereof. Examples of high-k materials with a dielectric constant greater than 7.0 include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The gate dielectric films can further include dopants such as, for example, lanthanum and aluminum. The gate dielectric films can be formed by suitable deposition processes, for example, CVD, PECVD, atomic layer deposition (ALD), evaporation, physical vapor deposition (PVD), chemical solution deposition, or other like processes. The thickness of the gate dielectric films can vary depending on the deposition process as well as the composition and number of high-k dielectric materials used.

The gate conductor 212 can include doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further include dopants that are incorporated during or after deposition. In some embodiments of the invention, the gate conductor 212 can be a WFM deposited over the gate dielectric films 210 by a suitable deposition process, for example, CVD, PECVD, PVD, plating, thermal or e-beam evaporation, and sputtering. The type of WFM depends on the type of transistor and can differ between the nFET and pFET devices. P-type WFMs include compositions such as ruthenium, palladium, platinum, cobalt, nickel, and conductive metal oxides, or any combination thereof. N-type WFMs include compositions such as hafnium, zirconium, titanium, tantalum, aluminum, metal carbides (e.g., hafnium carbide, zirconium carbide, titanium carbide, and aluminum carbide), aluminides, or any combination thereof. The gate conductor 212 can further include a tungsten (W), titanium (Ti), aluminum (Al), cobalt (Co), or nickel (Ni) material over the WFM layer of the gate conductor 212. The gate conductor 212 can be deposited by a suitable deposition process, for example, CVD, PECVD, PVD, plating, thermal or e-beam evaporation, and sputtering.

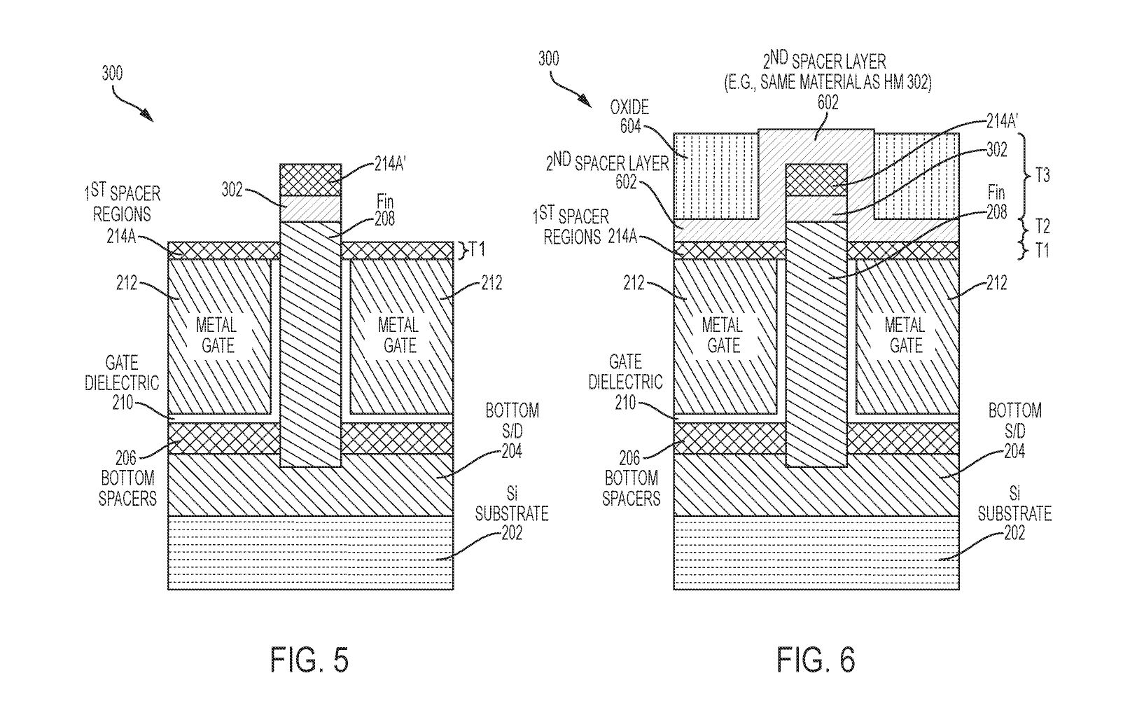

In FIG. 5, a first spacer region 214A has been formed over the gate 212 and the gate dielectric 210 and adjacent to a top portion of the channel fin 208. The first spacer region is formed to the thickness dimension T1 and can include a dielectric material, such as, for example, SiN, SiC, SiOC, SiCN, BN, SiBN, SiBCN, SiOCN, SiOₓN_{y}, and combinations thereof. The dielectric material can be a low-k material having a dielectric constant less than about 7, less than about 5, or even less than about 2.5. The first spacer region 214A can be formed using known deposition processes, such as, for example, CVD, PECVD, ALD, PVD, chemical solution deposition, or other like processes. In embodiments of the invention, the deposition process used to form the first spacer region 214A can also result in the deposition of second hard mask 214A′ over the hard mask 302.

In FIG. 6, a second spacer layer 602 is conformally deposited to the thickness dimension T2 over the first spacer region 214A, portions of the hard mask 302, and portions of the second hard mask 214A′. In embodiments of the invention, the second spacer layer 602 can be formed from the same or a different material than the hard mask 302. As also shown in FIG. 6, a dielectric material (e.g., a silicon oxide) is deposited over the second spacer layer 602 and polished back (e.g., using CMP) to the level shown in order to form oxide region 604. In embodiments of the invention, the oxide region 604 can be polished back to a thickness dimension T3.

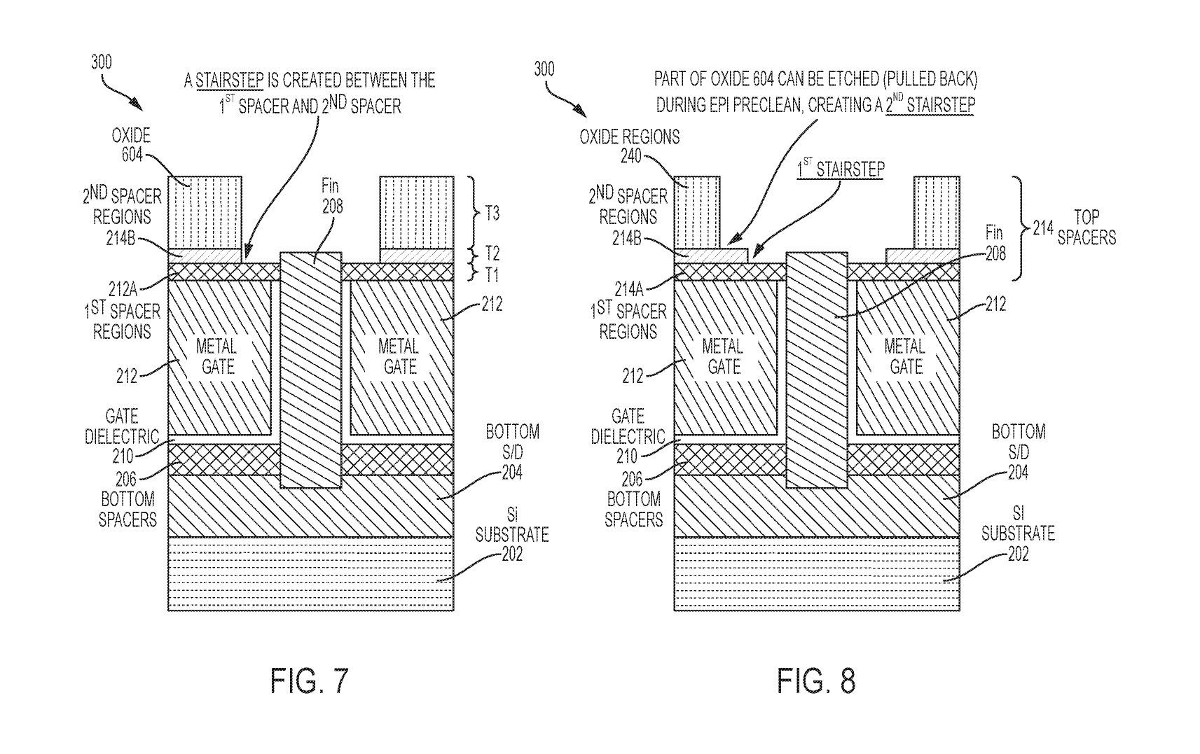

In FIG. 7, a RIE or equivalent process has been applied in order to remove the second hard mask 214A′ (shown in FIG. 6), the hard mask 302 (shown in FIG. 6), and the portions of the second spacer layer 602 that are not under the oxide region 604. This RIE process results in formation of the second spacer region 214B from the second spacer layer 602. The RIE process also exposes a top surface of the first spacer region 214A at a width dimension W1 (shown in FIG. 2B). The exposed top surface of the first spacer region 214A is essentially a “stairstep” between the first spacer region 214A and the second spacer region 214B.

In FIG. 8, the oxide region 604 (shown in FIG. 7) has been etched back to form an oxide region 240, and to expose a top surface of the second spacer region 214B at a width dimension W2 (shown in FIG. 2B). The exposed top surface of the second spacer region 214B is essentially a second “stairstep” between the second spacer region 214B and the oxide region 240. The oxide region 604 is etched back such that the top surface of the resulting oxide region 240 is at a width dimension W3 (shown in FIG. 2B). The etch back operations applied to the oxide region 604 results in the multi-dimensional top spacer 214 formed from the first spacer region 214A, the second spacer region 214B, and the oxide region 240 having thickness dimensions T1, T2, T3 (shown in FIG. 2B) and width dimensions W1, W2, W3 (shown in FIG. 2B). In embodiments of the invention, the pre-clean chemistries that are used to prepare the structure 300 for the formation of the top S/D region 216 (shown in FIGS. 2A and 2B) can also be used etch back the oxide region 604.

Returning back to FIGS. 2A and 2B, the top S/D region 216 has been formed over the exposed portion of the channel fin 208 (shown in FIG. 8) and the multi-dimensional top spacer 214 (shown in FIG. 8). In embodiments of the invention, the top S/D region 216 can be epitaxially grown, and top S/D region doping can be provided through in-situ doping during the epitaxial growth process, or through ion implantation after the top S/D region 216 is formed. In some embodiments, the top S/D region 216 can be formed by any suitable doping technique, including but not limited to, ion implantation, gas phase doping, plasma doping, plasma immersion ion implantation, cluster doping, infusion doping, liquid phase doping, solid phase doping, in-situ epitaxy growth, or any suitable combination of those techniques.

In accordance with embodiments of the invention, the multi-dimensional top spacer 214 results in (or defines) multiple different separation distances (e.g., T1, T2, T3) between the bottom surface 250 of the top S/D region 216 and a top surface of the gate conductor 212. In accordance with embodiments of the invention, the multi-dimensional top spacer 214 also results in (or defines) multiple different width dimensions (e.g., W1, W2, W3) in the bottom surface 250 of the top S/D region 216. In accordance with the various embodiments of the invention described herein, the multiple different separation distances (e.g., T1, T2, T3) are configured and arranged to achieve desired values for the parasitic capacitance 220. In accordance with the various embodiments of the invention described herein, the multiple different separation distances (e.g., T1, T2, T3) are configured and arranged to achieve desired values for the parasitic capacitance 220 and the S/D/channel resistance. In accordance with the various embodiments of the invention described herein, the multiple different separation distances (e.g., T1, T2, T3) and the multiple different width dimensions (e.g., W1, W2, W3) are configured and arranged to achieve desired values for the parasitic capacitance 220. In accordance with the various embodiments of the invention described herein, the multiple different separation distances (e.g., T1, T2, T3) and the multiple different width dimensions (e.g., W1, W2, W3) are configured and arranged to achieve desired values for the parasitic capacitance 220 and the S/D/channel resistance. In accordance with the various embodiments of the invention described herein, the multiple different separation distances (e.g., T1, T2, T3), the multiple different width dimensions (e.g., W1, W2, W3), and the volume of the top SD region 216 (e.g. the top S/D gate overlap 230 shown in FIG. 2A) are configured and arranged to achieve desired values for the parasitic capacitance 220 and the S/D/channel resistance.

The methods described herein are used in the fabrication of IC chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a { 100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of forming a semiconductor device, the method comprising:
forming a channel fin structure across from a major surface of a substrate;
forming a gate structure across from the major surface of the substrate and along a sidewall surface of the channel fin structure, wherein the gate structure comprises a gate structure top surface;
forming a source or drain (S/D) region having a S/D region bottom surface, wherein a first portion of the S/D region extends over the channel fin structure, wherein a second portion of the S/D region extends over the gate structure;
configuring a first portion of the S/D region bottom surface to have a first predetermined distance from a first portion of the gate structure top surface; and
configuring a second portion of the S/D region bottom surface to have a second predetermined distance from a second portion of the gate structure top surface;
wherein the first predetermined distance is less than the second predetermined distance.

2. The method of claim 1 further comprising:
configuring a size of the S/D region to define a predetermined S/D region volume; and
selecting the predetermined S/D volume and the first predetermined distance to provide a predetermined current resistance between the S/D region and the channel fin structure.

3. The method of claim 1 further comprising selecting the first predetermined distance and the second predetermined distance to control the amount of parasitic capacitance between the S/D region and the gate structure.

4. The method of claim 1 further comprising configuring a third portion of the S/D region bottom surface to have a third predetermined distance from a third portion of the gate structure top surface.

5. The method of claim 4, wherein the second predetermined distance is less than the third predetermined distance.

6. The method of claim 1 further comprising forming a top spacer.

7. The method of claim 6 further comprising configuring the top spacer to separate the first portion of the S/D region bottom surface from the first portion of the gate structure top surface by the first predetermined distance.

8. The method of claim 7 further comprising configuring the top spacer to separate the second portion of the S/D region bottom surface from the second portion of the gate structure top surface by the second predetermined distance.

9. The method of claim 5 further comprising forming a top spacer.

10. The method of claim 9 further comprising configuring the top spacer to separate the first portion of the S/D region bottom surface from the first portion of the gate structure top surface by the first predetermined distance.

11. The method of claim 10 further comprising configuring the top spacer to separate the second portion of the S/D region bottom surface from the second portion of the gate structure top surface by the second predetermined distance.

12. The method of claim 11 further comprising configuring the top spacer to separate the third portion of the S/D region bottom surface from the third portion of the gate structure top surface by the third predetermined distance.

13. A semiconductor device comprising:
a channel fin structure formed across from a major surface of a substrate;
a gate structure formed across from the major surface of the substrate and along a sidewall surface of the channel fin structure, wherein the gate structure comprises a gate structure top surface;
a source or drain (S/D) region having a S/D region bottom surface, wherein a first portion of the S/D region extends over the channel fin structure, wherein a second portion of the S/D region extends over the gate structure;
a first portion of the S/D region bottom surface configured to have a first predetermined distance from a first portion of the gate structure top surface; and
a second portion of the S/D region bottom surface configured to have a second predetermined distance from a second portion of the gate structure top surface;
wherein the first predetermined distance is less than the second predetermined distance.

14. The device of claim 13, wherein:
a size of the S/D region is configured to define a predetermined S/D region volume; and
the predetermined S/D volume and the first predetermined distance are configured to provide a predetermined current resistance between the S/D region and the channel fin structure.

15. The device of claim 13, wherein the first predetermined distance and the second predetermined distance are configured to control the amount of parasitic capacitance between the S/D region and the gate structure.

16. The device of claim 13 further comprising a third portion of the S/D region bottom surface configured to have a third predetermined distance from a third portion of the gate structure top surface.

17. The device of claim 16, wherein the second predetermined distance is less than the third predetermined distance.

18. The device of claim 13 further comprising a top spacer configured to:
separate the first portion of the S/D region bottom surface from the first portion of the gate structure top surface by the first predetermined distance; and
separate the second portion of the S/D region bottom surface from the second portion of the gate structure top surface by the second predetermined distance.

19. The device of claim 17 further comprising a top spacer configured to:
separate the first portion of the S/D region bottom surface from the first portion of the gate structure top surface by the first predetermined distance; and
separate the second portion of the S/D region bottom surface from the second portion of the gate structure top surface by the second predetermined distance.

20. The device of claim 19 further comprising the top spacer configured to separate the third portion of the S/D region bottom surface from the third portion of the gate structure top surface by the third predetermined distance.
